(19) United States
(12) Patent Application Publication
(10) Pub. No.: US 2009/0078943 A1
(43) Pub. Date: Mar. 26, 2009

(54) NITRIDE SEMICONDUCTOR DEVICE AND MANUFACTURING METHOD THEREOF

(75) Inventors: Hidetoshi ISHIDA, Osaka (JP); Tetsuzo UEDA, Osaka (JP); Daisuke UEDA, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 12/233,011

(22) Filed: Sep. 18, 2008

(30) Foreign Application Priority Data
Sep. 20, 2007 (JP) 2007-244508

(51) Int. Cl. H01L 29/15; H01L 21/00

(52) U.S. Cl. 257/77; 438/105; 257/E29.072; 257/E21.001

(57) ABSTRACT

A nitride semiconductor device mainly made of a nitride semiconductor material having excellent heat dissipation characteristics and great crystallinity and a method for manufacturing thereof are provided. The method for manufacturing the nitride semiconductor includes vapor-depositing a diamond layer on a silicon substrate, bonding an SOI substrate on a surface of the diamond layer, thinning the SOI substrate, epitaxially growing an GaN layer on the thinned SOI substrate, removing the silicon substrate, and bonding, on a rear-surface of the diamond layer, a material having a thermal conductivity greater than a thermal conductivity of the silicon substrate. The SOI substrate has an outermost surface layer and a silicon oxide layer. In the thinning, the SOI substrate is thinned by selectively removed through the silicon oxide layer, so that only the outermost surface layer is left.

### BACKGROUND OF THE INVENTION

(1) Field of the Invention

The present invention relates to nitride semiconductor devices and manufacturing methods thereof, and in particular, to a nitride semiconductor device used as a high-power device including a transistor made of GaN, and a manufacturing method thereof.

(2) Description of the Related Art

Once suffering from stagnation following the burst of the IT bubble in the year 2000, the recent power device market has enjoyed a steady growth to expand to be nearly a two-trillion-dollar market as of 2006. Key products of the power devices are the IGBT (Insulated Gate Bipolar Transistor), the MOSFET (Metal Oxide Semiconductor Field Effect Transistor) the silicon-controlled rectifier, and the SBD (Schottky Barrier Diode), all of which are made of silicon.

Performance of the devices, however, has almost reached to the material limit of silicon. Thus, a new device, made of a new power semiconductor material having superior characteristics to the characteristics of silicon materials, is desired. In particular, GaN and SiC are under rapid development, since expected to be power device materials for the next generation.

Among the power device materials for the next generation, an Field Effect Transistor (FET) made of a GaN-material is significantly promising since the FET achieves a high sheet carrier concentration as great as 10¹³ (cm⁻²) in the HEMT (High Electron Mobility Transistor) structure, as well as a feature that the FET is high in a breakdown field, compared with the silicon.

Meanwhile, because a GaN transistor can run a large amount of current in a relatively small device area, a drawback is observed in that the GaN transistor produces a large amount of heat. A band gap of a GaN material is three times as large as silicon, and an effect of a junction temperature rise to a device is small compared with the effect to a silicon device. Still, when designing a device, heat dissipation from the GaN device should be thoroughly taken into consideration in order to take a full advantage of the characteristics of the device.

Practically, most of GaN transistors have been fabricated on a sapphire substrate in an early stage of the development; however, techniques to fabricate a transistor on a SiC substrate and a silicon substrate are being established. Further, a GaN FET with diamond having a high thermal conductivity has also been proposed.

The following describes an FET made of a conventional nitride semiconductor material disclosed in Patent Reference 1: Japanese Patent No. 3481427, using FIG. 1. FIG. 1 is a cross-sectional view of a conventionally structured FET with a GaN layer epitaxially grown on a silicon substrate. The FET in FIG. 1 includes a silicon substrate 101, a diamond layer 102, a GaN buffer layer 103, and an n-type GaN layer 104. In the structure shown in FIG. 1, the diamond layer 102 having a significantly high thermal conductivity is formed on the silicon substrate 101 with relatively an excellent thermal conductivity. On the diamond layer 102, GaN-based materials are epitaxially grown.

According to Patent Reference 1, the structure in FIGS. 10A through 10E are formed by the gas source Molecular Beam Epitaxy (MBE) scheme employing the hot filament structure. First, a hydrogen gas is hydro-radicalized by a hot filament to the silicon substrate 101 heated to 950° C., and the surface of the silicon substrate 101 is cleaned. Then, with the temperature of the cleaned silicon substrate 101 set to 850° C., a methane and a hydrogen are radicalized by the hot filament to be radiated to the substrate. The diamond layer 102 having 200 Å in thickness is formed through this process. Next, the substrate temperature is set to 640° C., and the GaN buffer layer 103, with the carbon densely-doped, is formed. Finally, the substrate temperature is set to 850° C., and the n-type GaN layer grows.

Patent Reference 1 further discloses that the diamond is high in thermal conductivity, so that the above described structure is effective in improving heat dissipation efficiency of the device.

The above described conventionally structured FET is, however, has a diamond layer as thin as 500 Å or below, and thus, heat generated when bonding devices is not fully diffused to lateral orientation. In addition, the FET is not structured to improve heat dissipation characteristics up to the limit since the substrate of the FET is made of silicon. Moreover, since the difference between a lattice constant of the diamond layer and a lattice constant of the GaN layer is great, crystallinity of the GaN layer on the diamond layer is unfortunately inferior to crystallinity of the GaN layer on the conventional silicon substrate.

The present invention is conceived in view of the above problems and has an objective to provide a device having a GaN layer with particularly excellent heat dissipation characteristics and great crystallinity, and a manufacturing method thereof.

### SUMMARY OF THE INVENTION

In order to solve the above problems, a nitride semiconductor device of the present invention includes: a substrate; a high thermal conductivity layer, formed on the substrate, having a thermal conductivity higher than a thermal conductivity of the substrate; an intermediate layer formed on said high thermal conductivity layer; and a nitride semiconductor epitaxial layer formed on said intermediate layer.

The above structure enables nitride semiconductor materials having excellent crystallinity to be crystally-grown even though lattice mismatch between a high thermal conductivity layer and the Nitride semiconductor materials is great. Further, the high thermal conductivity layer can effectively improve heat dissipation specifications.

Here, the high thermal conductivity layer is preferably a layer of diamond.

This allows a high thermal conductivity layer having a diamond layer to obtain significantly excellent heat dissipation specifications.

The layer of diamond has a thickness ranging from 1 μm to 50 μm.

This can effectively utilize the diamond layer as a heat spreader of a high thermal conductivity layer, as well as avoid warping.

Further, the high thermal conductivity layer may be a layer of AlN.

This enables a high thermal conductivity layer to be formed at a relatively low cost.

Here, the intermediate layer may be mainly made of silicon.

This can achieve a small lattice mismatch rate since a nitride semiconductor layer crystal-grows on a silicon layer. As a result, the growing nitride semiconductor layer has excellent crystallinity.

Moreover, the thermal conductivity of the substrate is higher than a thermal conductivity of the intermediate layer.

Compared with the case where nitride semiconductor materials are grown with materials forming an intermediate layer as a substrate, this can significantly improve heat dissipation specifications.

In addition, the substrate may be mainly made of diamond.

This significantly improves heat dissipation characteristics since diamond has a high thermal conductivity.

Further, the substrate is mainly made of either copper or aluminum.

This can form a nitride semiconductor device having high heat dissipation characteristics at a low cost.

Moreover, the nitride semiconductor device may have a conductive material on a surface of either the high thermal conductivity layer or said intermediate layer.

In particular, either: the high thermal conductivity layer preferably has a surface with a part of both the nitride semiconductor epitaxial layer and the intermediate layer removed; or the intermediate layer preferably has another surface with a part of the nitride semiconductor epitaxial layer removed, and the conductive material is preferably patterned on the surface or the other surface having the removed part.

This enables a passive component having excellent heat dissipation characteristics to be formed on a metal substrate. A microstrip line and a capacitor including the metal substrate and a diamond layer can be the passive component.

In addition, the substrate may also be mainly made of alloy with either copper and tungsten, or copper and molybdenum.

In particular, the copper preferably accounts for 10 to 50% of the alloy.

This can form a passive component having excellent heat dissipation characteristics on the above metal substrates, as well as improve heat dissipation characteristics, since the metal substrates have a high thermal conductivity. Further, with either tungsten or molybdenum added to copper, thermal expansion coefficients of the metal substrates and thermal expansion coefficients of nitride semiconductor materials become close, and thus a crack and warping can be reduced. In particular, the above effects become significant when the copper accounts for 10 to 50% of the alloy.

Here, the intermediate layer may be mainly made of silicon carbide.

This can achieve a smaller lattice mismatch rate since a nitride semiconductor layer crystal-grows on a silicon carbide layer. As a result, the growing nitride semiconductor has excellent crystallinity. Further, silicon carbide has a higher thermal conductivity than a thermal conductivity of nitride semiconductor materials, and thus, the silicon carbide layer works as a heat spreader. Hence, heat dissipation specifications of a device are improved further.

The present invention is also a method, for manufacturing a nitride semiconductor device, including: forming a high thermal conductivity layer, on a first substrate, by vapor deposition, the high thermal conductivity layer having a thermal conductivity higher than a thermal conductivity of the first substrate; surface bonding, as an intermediate layer, a second substrate onto a surface of the high thermal conductivity layer formed in the forming the high thermal conductivity layer; and epitaxially growing GaN on the second substrate bonded in the surface bonding.

This forms GaN-based materials having excellent crystallinity on a high thermal conductivity layer. Hence, a GaN-based device having excellent heat dissipation characteristics can be realized.

Further, the present invention preferably includes thinning the second substrate between the surface bonding and the forming the second substrate nitride.

This can improve crystallinity of a GaN layer without deteriorating heat dissipation characteristics.

Here, the present invention may also include a manufacturing method that the second substrate may have a surface on which p-n junction is formed, and the surface having contact with the high thermal conductivity layer may be mainly made of p-type silicon, and the second substrate may be thinned by selective etching removing n-type silicon in the thinning the second substrate.

This allows the first substrate to be etched with excellent controllability, and thus only very thin p-type silicon is left. Hence, an intermediate layer having both of improved crystallinity and heat dissipation characteristics can be obtained.

In addition, the thinning the second substrate may also include, in advance, a process exposing an equivalent plane to a (100) plane on a surface of an n-type silicon substrate.

This achieves high-speed etching in a process selectively removing n-type silicon.

Here, the present invention may also include a manufacturing method that the second substrate may be an SOI (Silicon On Insulator) substrate having an outermost surface layer and a silicon oxide layer, and in the thinning the second substrate, the SOI substrate may be removed through the silicon oxide layer by selective etching, and the second substrate may be thinned to only leave the outermost surface layer.

This enables an HF-based wet etching scheme to be used for removing a silicon oxide layer on an SOI substrate. Hence, the SOI substrate can be selectively etched quickly with excellent controllability, so that a very thin outermost surface layer is left. Thus, an intermediate layer having both of improved crystallinity and heat dissipation characteristics can be obtained.

Here, the present invention may also include a manufacturing method that the second substrate may be a carbonized SOI substrate.

This enables nitride-based semiconductor materials to be crystally-grown above silicon of which surface is carbonized; namely SiC. Thus, a lattice mismatch rate of nitride-based semiconductor materials can be lowered compared with the case where the nitride-based semiconductor materials are crystally-grown on silicon, and thus, nitride-based materials having high crystallinity can be formed. Further, excellent heat dissipation characteristics can be obtained.

The present invention may also be a manufacturing method including: removing the first substrate after the forming the second substrate nitride; and rear-surface bonding, on a rear-surface of the high thermal conductivity layer, a material having a thermal conductivity higher than the thermal conductivity of the first substrate after the removing the first substrate.

This can form materials to be a thermal sink on a rear-surface of a high thermal conductivity material. The materials have lower melting points than: a deposition temperature of a high thermal conductivity layer; or crystal growth temperatures of nitride-based semiconductor materials.

Here, the present invention may include a method for manufacturing a nitride semiconductor device including: forming a high thermal conductivity layer, on a surface of a first substrate, by vapor deposition, the high thermal conductivity layer having a thermal conductivity higher than a thermal conductivity of the first substrate; surface bonding a second substrate onto a surface of the high thermal conductivity layer formed in the forming the high thermal conductivity layer; and epitaxially growing GaN on a rear-surface of the first substrate as an intermediate layer, after the surface bonding.

This enables nitride-based semiconductor materials to be formed, not on a surface of a high thermal conductivity layer which is relatively unstable in surface flatness, but on a flat surface of the first substrate; namely a high thermal conductivity layer. This enables nitride-based semiconductor materials having excellent crystallinity to be crystally-grown. Moreover no bonded interface in a bonding process exists between the high thermal conductivity layer and the nitride-based semiconductor materials. This improves heat dissipation characteristics.

The present invention may also be a manufacturing method including thinning the first substrate between the surface bonding and the forming the first substrate nitride.

This can improve crystallinity of a GaN layer without deteriorating heat dissipation characteristics.

Here, the manufacturing method preferably features that the substrate has a surface on which p-n junction is formed, and the surface having contact with the thermal conductivity layer is mainly made of p-type silicon, and the first substrate is thinned by selective etching removing n-type silicon in the thinning the first substrate.

This allows the first substrate to be etched with excellent controllability, and thus only very thin p-type silicon is left. Hence, an intermediate layer having both of improved crystallinity and heat dissipation characteristics can be obtained.

Moreover, the thinning the first substrate may include, in advance, a process exposing an equivalent plane to a (100) plane on a surface of an n-type silicon substrate.

This manufacturing method achieves high-speed etching in a process to selectively remove n-type silicon.

Here, the manufacturing method may feature that, the first substrate is an SOI substrate having an outermost surface layer and a silicon oxide layer, and in the thinning the first substrate, the SOI substrate is removed through the silicon oxide layer by selective etching, and the first substrate is thinned with only the outermost surface layer left.

This enables an HF-based wet etching scheme to be used for removing a silicon oxide layer on an SOI substrate. Hence, the SOI substrate can be selectively etched quickly with excellent controllability, so that a very thin outermost surface layer is left. Thus, an intermediate layer having both of improved crystallinity and heat dissipation characteristics can be obtained.

Here, the manufacturing method may also feature that the first substrate is a carbonized SOI substrate.

This enables nitride-base semiconductor materials to be crystally-grown above silicon with a surface thereof carbonized; namely SiC. Thus, a lattice mismatch rate of nitride-based semiconductor materials can be lowered compared with the case where the nitride-based semiconductor materials are crystally-grown on silicon, and thus, nitride-based materials having high crystallinity can be formed. Further, excellent heat dissipation characteristics can be obtained.

As described above, the nitride semiconductor device and the manufacturing method thereof in the present invention, can provide a device having a GaN layer with particularly excellent heat dissipation characteristics and great crystallinity.

### FURTHER INFORMATION ABOUT TECHNICAL BACKGROUND TO THIS APPLICATION

The disclosure of Japanese Patent Application No. 2007-244508 filed on Sep. 20, 2007 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view of a conventionally structured FET with a GaN layer epitaxially grown on a silicon substrate;

FIG. 2 is a cross-sectional view of a nitride semiconductor device in a first embodiment of the present invention;

FIG. 3 is a graph showing a relationship between thickness of a diamond layer and a junction temperature of the nitride semiconductor device;

FIGS. 4A through 4F are a flow sheet describing a manufacturing method of the nitride semiconductor device in the first embodiment of the present invention;

FIGS. 5A through 5F are a flow sheet describing a manufacturing method of a nitride semiconductor device in a second embodiment of the present invention;

FIG. 6 is a graph showing a selection ratio between n-type silicon and p-type silicon to boron concentration;

FIGS. 7A through 7F are a flow sheet describing a manufacturing method of a nitride semiconductor device in a third embodiment of the present invention;

FIGS. 8A through 8E are a flow sheet describing a manufacturing method of a nitride semiconductor device in a fourth embodiment of the present invention;

FIGS. 9A through 9E are a flow sheet describing a manufacturing method of a nitride semiconductor device in a fifth embodiment of the present invention; and

FIGS. 10A through 10E are a flow chart describing a manufacturing method of a nitride semiconductor device in a sixth embodiment of the present invention.

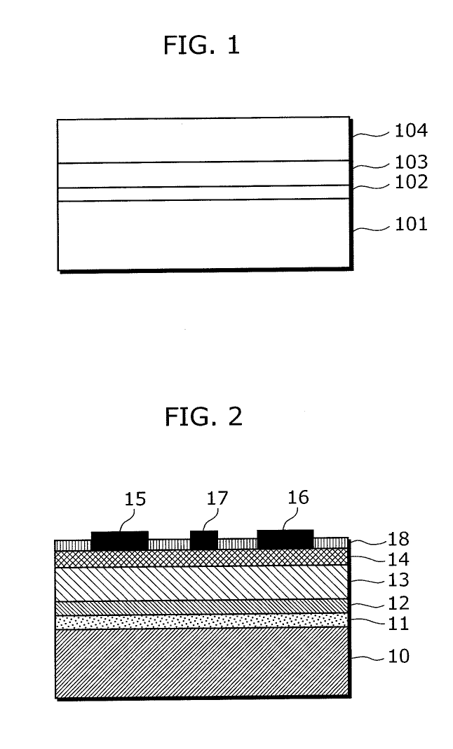

### DESCRIPTION OF THE PREFERRED EMBODIMENT(S)

### First Embodiment

A nitride semiconductor device in a first embodiment realizes an GaN epitaxial layer with excellent heat dissipation characteristics and crystallinity, by having diamond on a substrate, an intermediate layer on the diamond, and the GaN epitaxial layer on the intermediate layer.

The first embodiment of the present invention shall be described in detail, referring to the drawings, hereinafter.

FIG. 2 is a cross-sectional view of a nitride semiconductor device in the first embodiment of the present invention. The nitride semiconductor device in FIG. 2 has: a substrate 10, a diamond layer 11, a silicon carbide (SiC) layer 12, a GaN epitaxial layer 13, an AlGaN layer 14, a source electrode 15, a drain electrode 16, a gate electrode 17, and a passivation film 18.

The substrate 10 has a high thermal conductivity. The diamond layer 11 contributes to improving heat dissipation characteristics of the device since diamond has a high thermal conductivity.

The SiC layer 12 is inserted between the GaN epitaxial layer 13 and the diamond layer 11 as an intermediate layer.

The GaN epitaxial layer 13 is a material for a nitride semiconductor device, such as an FET for a power device, and included in a transistor.

Since a lattice mismatch rate between the diamond layer 11 and the GaN epitaxial layer 13 is high, the SiC layer 12, inserted as the intermediate layer between the diamond layer 11 and the GaN epitaxial layer 13, decreases the lattice mismatch rate when the GaN epitaxial layer 13 is formed. This significantly improves the crystallinity of the GaN epitaxial layer 13.

The AlGaN layer 14 is formed on the GaN epitaxial layer 13, and the AlGaN layer 14 and the GaN epitaxial layer 13 form a transistor.

The source electrode 15, the drain electrode 16, and the gate electrode 17 are respectively formed on the AlGaN layer 14.

The passivation film 18 coats: part of the source electrode 15, the drain electrode 16, and the gate electrode 17; and an outermost surface of the AlGaN layer 14.

It is noted that a stoichiometry ratio of the AlGaN layer 14 is, for example, Al_{0.2}Ga_{0.8}N, and a material for the passivation film 18 is, for example, SiN.

Further, the diamond layer 11 may also be replaced with an AlN layer. As well as the diamond layer 11, this also improves heat dissipation characteristics of the entire device, since the thermal conductivity of the AlN layer is high.

In addition, silicon may be used as the intermediate layer instead of the SiC layer 12 in order to narrow a large lattice constant difference between the GaN epitaxial layer 13 and the diamond layer 11.

Using silicon for an intermediate layer also improves the crystallinity of the GaN epitaxial layer 13.

Meanwhile, using SiC for an intermediate layer can improve: heat dissipation capacity of the nitride semiconductor device in the present invention; as well as crystallinity of the GaN epitaxial layer 13.

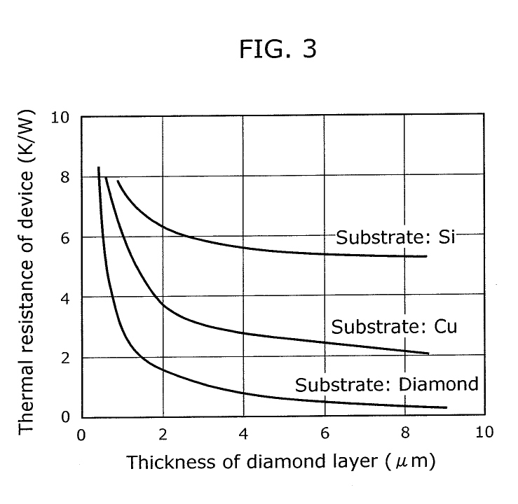

FIG. 3 is a graph representing a relationship between thickness of a diamond layer and a junction temperature of the nitride semiconductor device. The graph in FIG. 3 results from calculating a thermal resistance for each substrate materials by the finite-element method. Materials having a high thermal conductivity are selected as the substrate materials.

FIG. 3 shows that a diamond layer having 1 μm or more in thickness is highly effective to be a diamond layer heat spreader.

It is noted that the thickness of the diamond layer is preferable to be 50 μm or smaller in thickness in order to avoid warping.

FIG. 3 also shows that a metal-based material and diamond having a high thermal conductivity as a substrate material significantly decreases a junction temperature of the nitride semiconductor device.

Hence, the above described materials for the structure of the present invention decrease a junction temperature of the nitride semiconductor device.

Here, a material for the substrate 10 having a high thermal conductivity preferably has a higher thermal conductivity than the thermal conductivity of the intermediate layer; that is, diamond is most desirable.

Meanwhile, use of copper or aluminum for the substrate 10 can realize a nitride semiconductor device with a relatively low thermal resistance at a low cost. Further, the nitride-based semiconductor materials can be partially removed in order to expose the diamond layer 11, so that a transmission line such as a microstrip line and a capacitor can be formed on the diamond layer 11.

In addition, as a material for a substrate having a high thermal conductivity, alloy with copper and tungsten, or alloy with copper and molybdenum can realize a nitride semiconductor device with totally small warping, as well as with a relatively thermal resistance.

This takes advantage of the fact that a thermal expansion coefficient of the GaN layer and the AlGaN layer, nitride-based materials, is relatively close to a thermal expansion coefficient of the above sets of alloy.

In particular, the above effects become significant with the copper accounting for 10 to 50% of the alloy. Because of the above reasons, either the alloy with copper and tungsten, or the alloy with copper and molybdenum may be used as a material for the substrate 10.

Next, a manufacturing process of the above nitride semiconductor device shall be described.

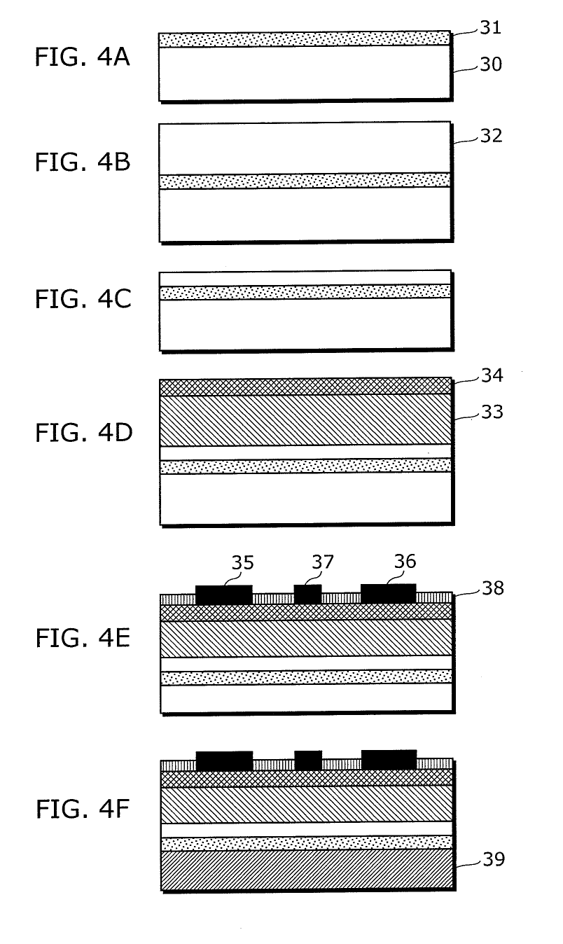

FIGS. 4A through 4F are a flow sheet describing a manufacturing method of the nitride semiconductor device in the first embodiment of the present invention.

First, a diamond layer 31 is chemically vapor-deposited (CVD) on a silicon substrate 30 (FIG. 4A). The hot-filament CVD scheme is preferable to the deposition scheme. Instead, the plasma-activated chemical vapor deposition (plasma CVD) scheme may also be applicable. Using hydrogen as carrier gas, and methane as source gas, the diamond layer 31 is deposited at a substrate temperature of 850° C., for example.

Next, a silicon substrate 32 having a (111) plane as a main surface is bonded onto a surface of the diamond layer 31 (FIG. 4B). Strength of the bonding can be increased by either: planarizing the diamond layer 31 by polishing prior to the bonding; or depositing a flattening film such as a Phospho-Silicate-Glass (PSG) on the diamond layer 31, using the CVD scheme.

Next, the bonded silicon substrate 32 is thinned to 50 μm or thinner by rear-surface polishing, and finalized to be a mirror plane (FIG. 4C).

On the mirror polished silicon substrate 32, nitride-based semiconductor materials are deposited, using the MOCVD scheme. A GaN epitaxial layer 33 and an AlGaN layer 34 are grown on the silicon substrate 32, with a buffer layer therebetween. Here, the buffer layer preserves lattice matching with the GaN epitaxial layer 33 and thermal conductivity (FIG. 4D).

On the substrate formed as described above, a source electrode 35, a drain electrode 36, and a gate electrode 37 are formed, and then a passivation film 38 made of SiN is formed (FIG. 4E).

Finally, the silicon substrate 30 is completely removed by polishing and wet etching, so that the rear-surface of the diamond layer 31 is exposed. Then, a high heat dissipation substrate 39 is bonded on the rear-surface of the diamond layer 31 (FIG. 4F). Here, the high heat dissipation substrate 39 has a higher thermal conductivity than a thermal conductivity of the silicon substrate 32 as an intermediate layer.

A typical diamond layer deposited on a silicon substrate is polycrystal, and thus, nitride-based semiconductor materials cannot be crystally grown on the diamond layer. The above described production scheme, however, allows nitride-based semiconductor materials having excellent crystallinity to be formed on a diamond layer.

As described above, the nitride semiconductor device in the first embodiment realizes an epitaxial layer with excellent dissipation characteristics and crystallinity, by having diamond on the substrate, an intermediate layer on the diamond, and a GaN epitaxial layer on the intermediate layer. In particular, since SiC and silicon are selected for the intermediate layer, crystallinity of the GaN epitaxial layer drastically improves. Moreover, the heat dissipation characteristics of the entire device significantly improve by using, as a substrate, either diamond, copper, aluminum, alloy with copper and tungsten, or alloy with copper and molybdenum.

### Second Embodiment

A nitride semiconductor device in a second embodiment reduces a rise in a thermal resistance in an intermediate layer therein since a silicon layer of the nitride semiconductor device as the intermediate layer is thinned by the ion implantation scheme and selective etching. As a result, the heat dissipation characteristics of the nitride semiconductor device further improve.

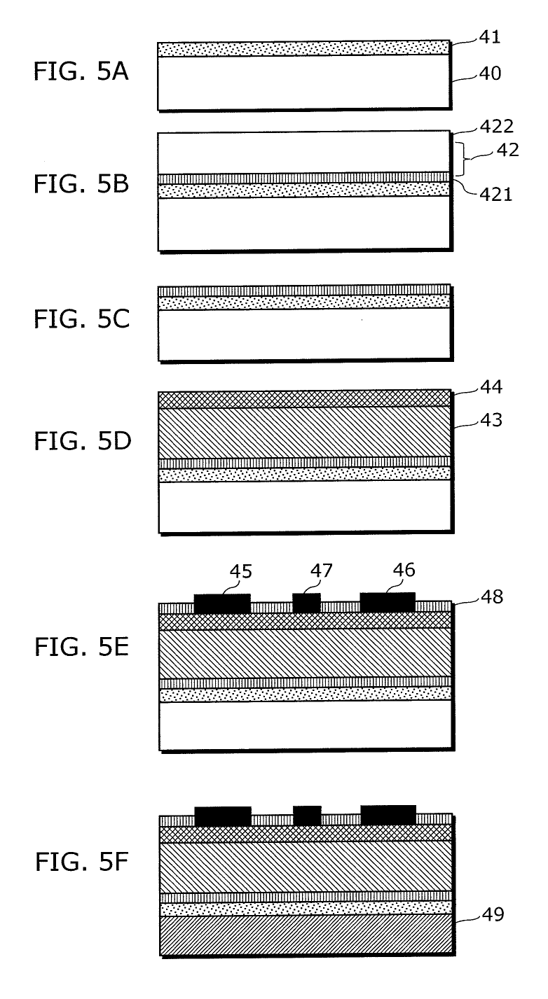

FIGS. 5A through 5F are a flow sheet describing a manufacturing method of the nitride semiconductor device in the second embodiment of the present invention.

First, a diamond layer 41 is chemically vapor-deposited on a silicon substrate 40. The hot-filament CVD scheme is preferable to the deposition scheme. Instead, the plasma CVD scheme may also be applicable. Using hydrogen as carrier gas, and methane as source gas, the diamond layer 41 is deposited at a substrate temperature of 850° C., for example (FIG. 5A).

It is noted that the diamond layer 41 may also be replaced with an AlN layer. As well as the diamond layer 41, this also improves dissipation characteristics of the entire device, since the thermal conductivity of the AlN layer is high.

Next, a silicon substrate 42 having a (111) plane as a main surface is bonded. Here, the silicon substrate 42 has: a surface on which p-n junction is formed; and a p-typed outermost surface (FIG. 5B). The silicon substrate 42 with the outermost surface p-typed is obtained by, for example, implanting boron into a surface of an n-type silicon substrate as much as 1×10²⁰ (cm⁻³) in boron concentration, using the ion implantation scheme.

Strength of the bonding can be increased by either: planarizing the diamond layer 41 by chemical polishing prior to the bonding; or depositing a flattening film such as a Phospho-Silicate-Glass (PSG) on the diamond layer 41, using the CVD scheme.

Next, only an n-type silicon layer 422 on the rear-surface of the bonded silicon substrate is selectively etched, using alkali-based etchant heated up to 80° C. (Tetramethyl Ammonium Hydroxide (TMAH), for example), so that only a p-type silicon layer 421 is left (FIG. 5C). The thinning process enables only a significantly thin p-typed silicon layer to be left.

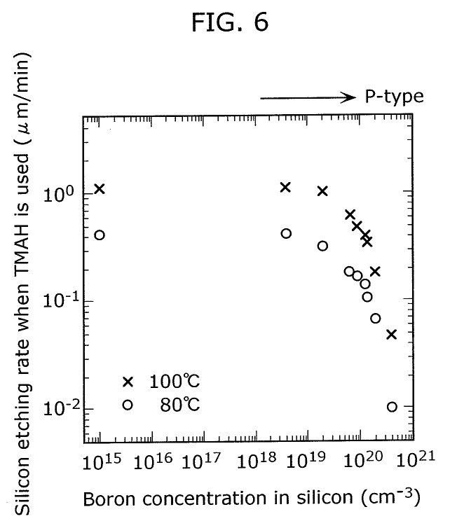

FIG. 6 is a graph showing a selection ratio between n-type silicon and p-type silicon to boron concentration. In the graph of the FIG. 6, the abscissa represents a boron implant concentration, and the ordinate represents a silicon etching rate when the TMAH is used. FIG. 6 shows that the silicon layer 421 becomes more p-typed at higher boron concentrations represented on the abscissa. According to the graph, the selection ratio between the p-type silicon and the n-type silicon with no boron implanted is found to improve 10 or greater when boron concentration is greater than 1×10¹⁹ (cm⁻³).

The description shall be continued, going back to FIGS. 5A through 5F. In FIG. 5C, introducing beforehand a process to expose a (100) plane on the surface of an n-type silicon layer 422 can significantly improves a speed in the selective etching. This takes advantage of the fact that the etching speed on the (100) plane is faster than the etching speed on the (111) plane.

Following the removal of the n-type silicon layer 422 as described above, nitride-based materials are deposited on the p-type silicon layer 421, using the MOSVD scheme. A GaN epitaxial layer 43 and an AlGaN layer 44 are grown on the p-type silicon layer 421, with a buffer layer therebetween. Here, the buffer layer preserves lattice matching with the GaN epitaxial layer 43 and a thermal conductivity (FIG. 5D).

Next, on the substrate formed as described above, a source electrode 45, a drain electrode 46, and a gate electrode 47 are formed, and then a passivation film 48 made of SiN is formed (FIG. 5E).

Finally, the silicon substrate 40 is completely removed by polishing and wet etching, so that the diamond layer 31 is exposed. Then, a high heat dissipation substrate 49 is bonded on the rear-surface of the diamond layer 41 (FIG. 5F). Here, the high heat dissipation substrate 49 has a higher thermal conductivity than a thermal conductivity of the p-type silicon layer 421 as an intermediate layer.

As described above, the manufacturing method of the nitride semiconductor device in the second embodiment of the present invention can realize a semiconductor device with a low thermal resistance because: nitride-based materials with excellent crystallinity are formed on a monocrystal silicon layer on a multicrystal diamond layer; and, in addition, the monocrystal silicon layer on the diamond layer can be thinned.

### Third Embodiment

A nitride-based semiconductor device in a third embodiment includes a more thinned intermediate layer produced by processing an SOI (Silicon On Insulator) substrate to form the intermediate layer out of an outmost surface of the SOI substrate. As a result, a rise in a thermal resistance in the intermediate layer is reduced, and the heat dissipation characteristics of the nitride semiconductor device further improve. In addition, by processing a carbonized SOI substrate to form an intermediate layer out of SiC, the outermost surface layer of the SOI substrate, crystallinity of a GaN layer and the thermal conductivity of the entire nitride semiconductor device further improve.

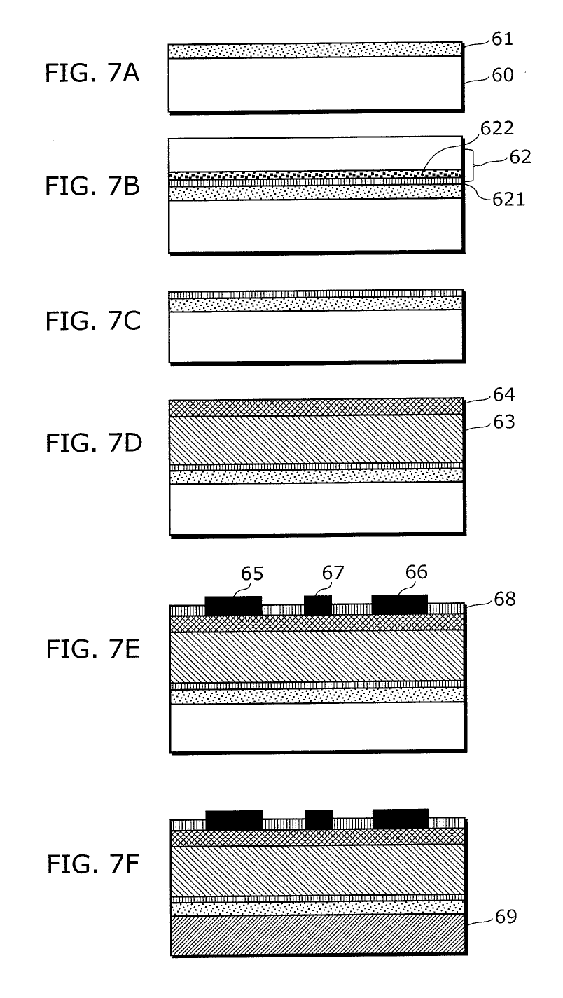

FIGS. 7A through 7F are a flow sheet describing a manufacturing method of the nitride semiconductor device in the third embodiment of the present invention.

First, a diamond layer 61 is chemically vapor-deposited on a silicon substrate 60 (FIG. 7A). The hot-filament CVD scheme is preferable to the deposition scheme. Instead, the plasma CVD scheme may also be applicable. Using hydrogen as carrier gas, and methane as source gas, the diamond layer 61 is deposited at a substrate temperature of 850° C., for example.

It is noted that the diamond layer 61 may also be replaced with an AlN layer. As well as the diamond layer 61, this also improves dissipation characteristics of the entire device, since the thermal conductivity of the AlN layer is high.

Then, an SOI substrate 62, either having a (111) plane as a main surface or carbonized, is bonded (FIG. 7B). Next, the rear-surface of the bonded SOI substrate 62 is selectively etched, using etching gas (XeF, for example) to leave an outermost surface layer 621, and a silicon oxide layer 622.

Then, the silicon oxide layer 622 is removed, using the HF-based wet etching scheme or the CHF₃-based dry etching scheme, so that only the outermost surface layer 621 layer is left.

On the outermost surface layer 621 layer, nitride-based semiconductor materials are deposited, using the MOCVD scheme. A GaN epitaxial layer 63 and an AlGaN layer 64 are grown on the outermost surface layer 621 layer with a buffer layer therebetween. Here, the buffer layer preserves lattice matching with the GaN epitaxial layer 63 and a thermal conductivity (FIG. 7D).

On the substrate formed as described above, a source electrode 65, a drain electrode 66, and a gate electrode 67 are formed, and then a passivation film 68 made of SiN is formed (FIG. 7E).

Finally, the silicon substrate 60 is completely removed by polishing and wet etching, so that the diamond layer 61 is exposed. Then, a high heat dissipation substrate 69 is bonded on the rear-surface of the diamond layer 61 (FIG. 7F). Here, the high heat dissipation substrate 69 has a higher thermal conductivity than a thermal conductivity of the outermost layer 621 as an intermediate layer.

Here, in the case where the outermost surface layer 621 of the SOI substrate 62 is carbonized, nitride-based semiconductor materials crystal-grows on carbonized silicon; namely, SiC. A lattice mismatch rate of GaN, one of nitride-based materials, to SiC is lower than a lattice mismatch rate of GaN to silicon, for example. Thus, crystallinity of the nitride-based materials improves.

Further, a thermal conductivity of SiC is greater than a thermal conductivity of silicon. Hence, a nitride semiconductor device having a smaller thermal resistance is realized.

As mentioned above, the manufacturing method of the nitride semiconductor device in the third embodiment of the present invention can realize a semiconductor material with a low thermal resistance since the manufacturing method can achieve: to form, on a monocrystal silicon layer, or SiC on multicrystal diamond layer, nitride-based semiconductor materials having excellent crystallinity; and further to thin the monocrystal silicon layer or the SiC on the multicrystal diamond layer.

### Fourth Embodiment

A nitride semiconductor device in a fourth embodiment uses, as an intermediate layer, a thinned rear-surface of a silicon substrate, the rear-surface having a diamond layer deposited thereon. Thus, heat, generated from bonded part of GaN-based semiconductor layers of the nitride semiconductor device, can be diffused to lateral orientation on a diamond layer, a heat spreader, without conducting a bonded interface. As a result, the nitride semiconductor device achieves a low thermal resistance. Moreover, a manufacturing method in the present invention allows a complex bonding process to be completed in one time.

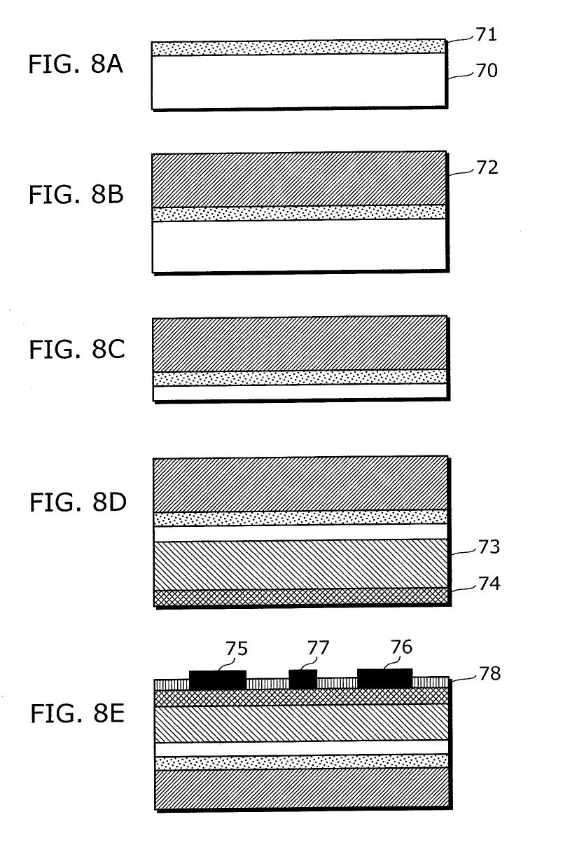

FIGS. 8A through 8E are a flow sheet describing the manufacturing method of the nitride semiconductor device in the fourth embodiment of the present invention.

First, a diamond layer 71 is chemically vapor-deposited on a surface of a silicon substrate 70 having a (111) plane as a main surface (FIG. 8A). The hot-filament CVD scheme is preferable to the deposition scheme. Instead, the plasma CVD scheme may also be applicable. Using hydrogen as carrier gas, and methane as source gas, the diamond layer 71 is deposited at a substrate temperature of 850° C., for example.

It is noted that the diamond layer 71 may also be replaced with an AlN layer. As well as the diamond layer 71, this also improves dissipation characteristics of the entire device, since the thermal conductivity of the AlN layer is high.

Next, a high heat dissipation substrate 72 having a high thermal conductivity is bonded onto the diamond layer 71 (FIG. 8B).

Strength of the bonding can be increased by either: planarizing the diamond layer 71 by polishing prior to the bonding; or depositing a flattening film such as a PSG on the diamond layer 71, using the CVD scheme.

Here, a material for the high heat dissipation substrate 72, one of copper, aluminum, alloy with copper and tungsten, or alloy with copper and molybdenum, as well as diamond, is preferable.

As a material for the high heat dissipation substrate 72, diamond is most desirable. Meanwhile, copper or aluminum for the substrate 10 can realize a nitride semiconductor device with a relatively low thermal resistance at a low cost. Further, nitride-based semiconductor materials can be partially removed in order to expose the diamond layer 71, so that a transmission line can be formed on the diamond layer 71. In addition, the alloy with copper and tungsten, or the alloy with copper and molybdenum can realize a nitride semiconductor device with totally small warping, as well as with a relatively low thermal resistance.

Next, the silicon substrate 70 is thinned to 50 μm or thinner by rear-surface polishing, and finalized to be a mirror plane (FIG. 8C).

On the rear-surface of the mirror polished and thinned silicon substrate 70, nitride-based semiconductor materials are deposited, using the MOCVD scheme. A GaN epitaxial layer 73 and an AlGaN layer 74 are grown on the rear-surface of the silicon substrate 70 with a buffer layer therebetween. Here, the buffer layer preserves lattice matching with the GaN epitaxial layer 73 and a thermal conductivity (FIG. 8D).

On the substrate formed as described above, a source electrode 75, a drain electrode 76, and a gate electrode 77 are formed, and then a passivation film 78 made of SiN is formed (FIG. 8E).

A typical diamond layer deposited on a silicon substrate is polycrystal, and thus, nitride-based semiconductor materials cannot be crystally grown on the diamond layer. The above described production scheme, however, allows nitride-based semiconductor materials having excellent crystallinity to be formed on a silicon substrate on which a diamond layer deposited. Thus, heat, generated from bonded part of the GaN-based semiconductor layers of the nitride semiconductor device, can be diffused to lateral orientation on the diamond layer, a heat spreader, without conducting the bonded interface. As a result, the nitride semiconductor device achieves a low thermal resistance. Moreover, the manufacturing method in the present invention allows a complex bonding process to be completed in one time.

### Fifth Embodiment

A nitride semiconductor device in a fifth embodiment uses, as an intermediate layer, a silicon substrate with the rear-surface thereof thinned by a selective etching process, the silicon substrate, on which a diamond layer deposited, having p-n junction. Thus, heat, generated from bonded part of GaN-based semiconductor layers of the nitride semiconductor device, can be diffused to lateral orientation on a diamond layer, a heat spreader, without conducting a bonded interface on the GaN-based semiconductor layers. As a result, the nitride semiconductor device achieves a low thermal resistance. Moreover, the manufacturing method in the present invention allows a complex bonding process to be completed in one time. Further, a selective etching process performed on an n-type silicon layer decreases chip yield in a silicon removing process.

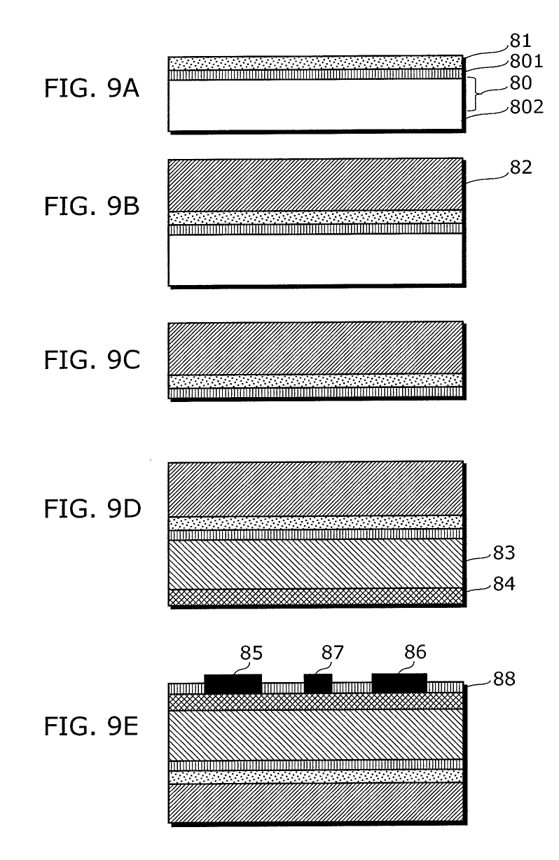

FIGS. 9A through 9E are a flow sheet describing the manufacturing method of the nitride semiconductor device in the fifth embodiment of the present invention.

First, a diamond layer 81 is chemically vapor-deposited on a surface of a silicon substrate 80 having a (111) plane as a main plane. Here, the silicon substrate 80 has: a surface on which p-n junction is formed; and a p-typed outermost surface layer (FIG. 9A).

The silicon substrate 80 with the outermost surface layer p-typed is obtained by, for example, implanting boron into a surface of an n-type silicon substrate as much as 1×10²⁰ (cm⁻³) in boron concentration, using the ion implantation scheme.

The hot-filament CVD scheme is preferable to the deposition scheme of the diamond layer 81. Instead, the plasma CVD scheme may also be applicable. Using hydrogen as carrier gas, and methane as source gas, the diamond layer 81 is deposited at a substrate temperature of 850° C., for example.

It is noted that the diamond layer 81 may also be replaced with an AlN layer. As well as the diamond layer 81, this also improves dissipation characteristics of the entire device, since the thermal conductivity of the AlN layer is high.

Next, a high heat dissipation substrate 82 having a high thermal conductivity is bonded onto the diamond layer 81 (FIG. 9B).

Strength of the bonding can be increased by either: planarizing the diamond layer 81 by polishing prior to the bonding; or depositing a flattening film such as a PSG on the diamond layer 81, using the CVD scheme.

Here, as a material for the high heat dissipation substrate 82, one of copper, aluminum, alloy with copper and tungsten, or alloy with copper and molybdenum, as well as diamond, is preferable.

As a material for the high heat dissipation substrate 82, diamond is most desirable. Meanwhile, copper or aluminum for the high heat dissipation substrate 82 can realize a nitride semiconductor with a relatively low thermal resistance at a low cost. Further, nitride-based semiconductor materials can be partially removed in order to expose the diamond layer 81, so that a transmission line can be formed on the diamond layer 81. In addition, alloy with copper and tungsten, or alloy with copper and molybdenum can realize a nitride semiconductor device with totally small warping, as well as with a relatively low thermal resistance.

Next, only an n-type silicon layer 802 of a rear-surface of the silicon substrate 80 is selectively etched, using alkali-based etchant heated up to 80° C. (Tetramethyl Ammonium Hydroxide (TMAH), for example), so that only a p-type silicon layer 801 is left (FIG. 9C). Here, the rear-surface of the silicon substrate 80 has a p-typed outermost layer. The thinning process enables a significantly thin p-typed silicon layer to be left. In this selective etching process, introducing beforehand a process to expose a (100) plane on the surface of an n-type silicon layer 802 can significantly improves a speed in the selective etching. This takes advantage of the fact that the etching speed on the (100) plane is faster than the etching speed on the (111) plane.

Following the above process, nitride-based semiconductor materials are deposited on: a surface on which the n-type silicon layer 802 is removed; and a rear-surface of the p-type silicon layer 801, using the MOCVD scheme. A GaN epitaxial layer 83 and an AlGaN layer 84 are grown on the rear-surface of the p-type silicon layer 802 with a buffer layer therebetween. Here, the buffer layer preserves lattice matching with the GaN epitaxial layer 83 and a thermal conductivity (FIG. 9D).

On the substrate formed as described above, a source electrode 85, a drain electrode 86, and a gate electrode 87 are formed, and then a passivation film 88 made of SiN is formed (FIG. 9E).

A typical diamond layer deposited on a silicon substrate is polycrystal, and thus, nitride-based semiconductor materials cannot be crystally grown on the diamond layer. The above described production scheme, however, allows nitride-based semiconductor materials having excellent crystallinity to be formed on a silicon substrate on which a diamond layer deposited. Thus, heat, generated from bonded part of the GaN-based semiconductor layers of the nitride semiconductor device, can be diffused to lateral orientation on the diamond layer, a heat spreader, without conducting the bonded interface on the GaN-based semiconductor layers. As a result, the nitride semiconductor device achieves a low thermal resistance. Moreover, the manufacturing method in the present invention allows a complex bonding process to be completed in one time.

Further, a selective etching process performed on an n-type silicon layer decreases chip yield in a silicon removing process.

### Sixth Embodiment

A nitride semiconductor device in a sixth embodiment uses, as an intermediate layer, an SOI substrate, on which a diamond layer deposited, thinned by a selective etching process. Thus, heat, generated from bonded part of GaN-based semiconductor layers of the nitride semiconductor device, can be diffused to lateral orientation on a diamond layer, a heat spreader, without conducting through a bonded interface on the GaN-based semiconductor layers.

As a result, the nitride semiconductor device achieves a low thermal resistance. Moreover, the manufacturing method in the present invention allows a complex bonding process to be completed in one time. Further, a selective etching process performed on an n-type silicon layer decreases chip yield in a silicon removing process.

Here, in the case where an outermost surface layer on the SOI substrate is carbonized, nitride-based semiconductor materials can crystal-grow on carbonized silicon; namely, SiC. A lattice mismatch rate of the nitride-based materials; namely GaN to SiC, is lower than a lattice mismatch rate of GaN to silicon, for example. Thus, crystallinity of the nitride-based materials improves. Further, a thermal conductivity of SiC is greater than a thermal conductivity of silicon. Hence, a nitride semiconductor device having smaller thermal resistance is realized.

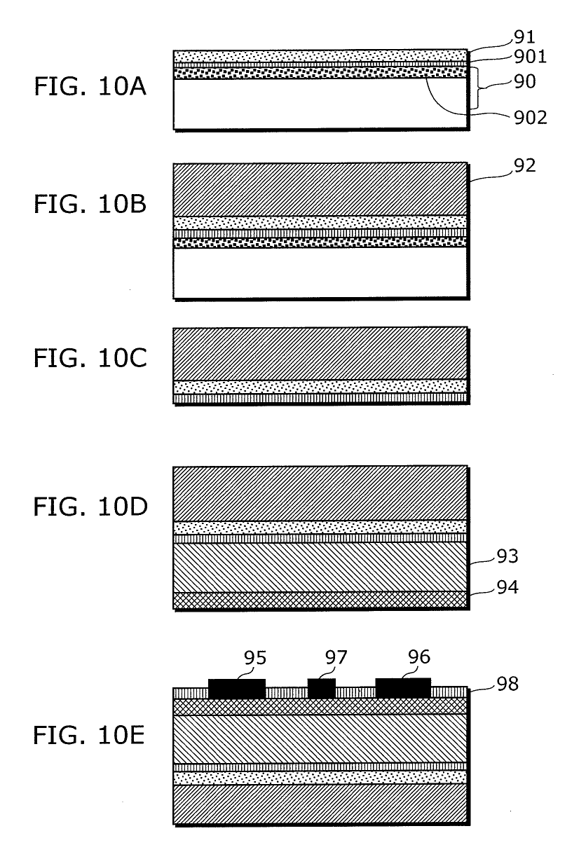

FIGS. 10A through 10E are a flow sheet describing the manufacturing method of the nitride semiconductor device in the sixth embodiment of the present invention.

First, a diamond layer 91 is chemically vapor-deposited on an SOI substrate 90 having: a (111) plane as a main plane; or the surface thereof being carbonized (FIG. 10A). The hot-filament CVD scheme is preferable for the deposition scheme of the diamond layer 91. Instead, the plasma CVD scheme may also be applicable. Using hydrogen as carrier gas, and methane as source gas, the diamond layer 91 is deposited at a substrate temperature of 850° C., for example.

It is noted that the diamond layer 91 may also be replaced with an AlN layer. As well as the diamond layer 91, this also improves dissipation characteristics of the entire device, since the thermal conductivity of the AlN layer is high.

Next, a high heat dissipation substrate 92 having a high thermal conductivity is bonded onto the diamond layer 91 (FIG. 10B).

Strength of the bonding can be increased by either: planarizing the diamond layer 91 by polishing prior to the bonding; or depositing a flattening film such as a PSG on the diamond layer 91, using the CVD scheme.

Here, as a material for the high heat dissipation substrate 92, one of copper, aluminum, alloy with copper and tungsten, or alloy with copper and molybdenum, as well as diamond, is preferable.

As a material for the high heat dissipation substrate 92, diamond is most desirable. Meanwhile, copper or aluminum for the high heat dissipation substrate 92 can realize a nitride semiconductor with a relatively low thermal resistance at a low cost. Further, nitride-based semiconductor materials can be partially removed in order to expose the diamond layer 81, so that a transmission line can be formed on the diamond layer 91. In addition, the alloy with copper and tungsten, or the alloy with copper and molybdenum can realize a nitride semiconductor device with totally small warping, as well as with a relatively low thermal resistance.

Next, the rear-surface of the SOI substrate 90 is selectively etched, using etching gas (XeF, for example) to leave an outermost surface layer 901, and a silicon oxide layer 902. Then, the silicon oxide layer 902 is removed, using an HF-based wet etching scheme or CHF₃-based dry etching scheme, and leave only the outermost surface layer 901 (FIG. 10C).

On the outermost surface layer 901, nitride-based semiconductor materials are deposited, using the MOCVD scheme. A GaN epitaxial layer 93 and an AlGaN layer 94 are grown on the outermost surface layer 901 with a buffer layer therebetween. Here, the buffer layer preserves lattice matching with the GaN epitaxial layer 93 and a thermal conductivity (FIG. 10D).

On the substrate formed as described above, a source electrode 95, a drain electrode 96, and a gate electrode 97 are formed, and then a passivation film 98 made of SiN is formed (FIG. 10E).

A typical diamond layer deposited on a silicon substrate is polycrystal, and thus, nitride-based semiconductor materials cannot be crystally grown on the diamond layer. The above described production scheme, however, allows nitride-based semiconductor materials having excellent crystallinity to be formed on a silicon substrate on which a diamond layer deposited. Thus, heat, generated from bonded part of the GaN-based semiconductor layers of the nitride semiconductor device, can be diffused to lateral orientation on the diamond layer, a heat spreader, without conducting the bonded interface on the GaN-based semiconductor layers. As a result, the nitride semiconductor device achieves a low thermal resistance. Moreover, the manufacturing method in the present invention allows a complex bonding process to be completed in one time.

Further, a selective etching process of silicon decreases chip yield in a silicon removing process.

Here, in the case where the outermost surface layer 901 on the SOI substrate 90 is carbonized, nitride-based semiconductor materials can crystal-grow on carbonized silicon; namely, SiC. A lattice mismatch rate of the nitride-based materials; namely GaN to SiC, is lower than a lattice mismatch rate of GaN to silicon, for example. Thus, crystallinity of the nitride-based materials improves. Further, a thermal conductivity of SiC is greater than a thermal conductivity of silicon. Hence, a nitride semiconductor device having smaller thermal resistance is realized.

As described above, the manufacturing method of the present invention can form, on a high thermal conductivity layer, nitride-based semiconductor materials having excellent crystallinity, since the manufacturing method can selectively form either a monocrystal silicon layer, or an SiC layer on a multicrystal diamond layer or an AlN layer. Further, silicon or the SiC on the high thermal conductivity layer can be thinned, which realizes a semiconductor device having a low thermal resistance.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is useful for a transmission amplifier, for a cellular phone base station, having a build-in nitride semiconductor device. In particular, the present invention is most desirable for a power amplifier requiring a high-output and high heat dissipation characteristics.

What is claimed is:

1. A nitride semiconductor device, comprising:
a substrate;
a high thermal conductivity layer, formed on said substrate, having a thermal conductivity higher than a thermal conductivity of said substrate;
an intermediate layer formed on said high thermal conductivity layer; and
a nitride semiconductor epitaxial layer formed on said intermediate layer.

2. The nitride semiconductor device according to claim 1,
wherein said high thermal conductivity layer is a layer of diamond.

3. The nitride semiconductor device according to claim 2,
wherein said layer of diamond has a thickness ranging from 1 μm to 50 μm.

4. The nitride semiconductor device according to claim 1,
wherein said high thermal conductivity layer is a layer of AlN.

5. The nitride semiconductor device according to claim 1,
wherein said intermediate layer is mainly made of silicon.

6. The nitride semiconductor device according to claim 5,
wherein the thermal conductivity of said substrate is higher than a thermal conductivity of said intermediate layer.

7. The nitride semiconductor device according to claim 5,
wherein said substrate is mainly made of diamond.

8. The nitride semiconductor device according to claim 5,
wherein said substrate is mainly made of either copper or aluminum.

9. The nitride semiconductor device according to claim 8,
wherein, said nitride semiconductor device has a conductive material on a surface of either said high thermal conductivity layer or said intermediate layer.

10. The nitride semiconductor device according to claim 9,
wherein either: said high thermal conductivity layer has a surface with a part of both said nitride semiconductor epitaxial layer and said intermediate layer removed; or said intermediate layer has another surface with a part of said nitride semiconductor epitaxial layer removed, and
the conductive material is patterned on the surface or the other surface having the removed part.

11. The nitride semiconductor device according to claim 5,
wherein said substrate is mainly made of alloy with either copper and tungsten, or copper and molybdenum.

12. The nitride semiconductor device according to claim 11,
wherein the copper accounts for 10 to 50% of the alloy.

13. The nitride semiconductor device according to claim 1,
wherein said intermediate layer is mainly made of silicon carbide.

14. The nitride semiconductor device according to claim 13,
wherein the thermal conductivity of said substrate is higher than a thermal conductivity of said intermediate layer.

15. The nitride semiconductor device according to claim 13,
wherein said substrate is mainly made of diamond.

16. The nitride semiconductor device according to claim 13,
wherein said substrate is mainly made of either copper or aluminum.

17. The nitride semiconductor device according to claim 16,
wherein, said nitride semiconductor device has a conductive material on a surface of either said high thermal conductivity layer or said intermediate layer.

18. The nitride semiconductor device according to claim 17,
wherein either: said high thermal conductivity layer has a surface with a part of both said nitride semiconductor epitaxial layer and said intermediate layer removed; or said intermediate layer has another surface with a part of said nitride semiconductor epitaxial layer removed, and
the conductive material is patterned on the surface or the other surface having the removed part.

19. The nitride semiconductor device according to claim 13,
wherein said substrate is mainly made of alloy with either copper and tungsten, or copper and molybdenum.

20. The nitride semiconductor device according to claim 19,
wherein the copper accounts for 10 to 50% of the alloy.

21. A method for manufacturing a nitride semiconductor device, comprising:
forming a high thermal conductivity layer, on a first substrate, by vapor deposition, the high thermal conductivity layer having a thermal conductivity higher than a thermal conductivity of the first substrate;
surface bonding, as an intermediate layer, a second substrate onto a surface of the high thermal conductivity layer formed in said forming the high thermal conductivity layer; and
epitaxially growing GaN on the second substrate bonded in said surface bonding.

22. The method for manufacturing the nitride semiconductor device according to claim 21, further including
thinning the second substrate between said surface bonding and said forming the second substrate nitride.

23. The method for manufacturing the nitride semiconductor device according to claim 22,
wherein the second substrate has a surface on which p-n junction is formed, and the surface having contact with the high thermal conductivity layer is mainly made of p-type silicon, and
the second substrate is thinned by selective etching removing n-type silicon in said thinning the second substrate.

24. The method for manufacturing the nitride semiconductor device according to claim 23,
wherein said thinning the second substrate includes, in advance, a process exposing an equivalent plane to a (100) plane on a surface of an n-type silicon substrate.

25. The method for manufacturing the nitride semiconductor device according to claim 22,
wherein the second substrate is an SOI (Silicon On Insulator) substrate having an outermost surface layer and a silicon oxide layer, and
in said thinning the second substrate, the SOI substrate is removed through the silicon oxide layer by selective etching, and the second substrate is thinned to only leave the outermost surface layer.

26. The method for manufacturing the nitride semiconductor device according to claim 25,
wherein the second substrate is a carbonized SOI substrate.

27. The method for manufacturing the nitride semiconductor device according to claim 21, further including:
removing the first substrate after said forming the second substrate nitride; and
rear-surface bonding, on a rear-surface of the high thermal conductivity layer, a material having a thermal conductivity higher than the thermal conductivity of the first substrate after said removing the first substrate.

28. The method for manufacturing the nitride semiconductor device according to claim 21,
wherein the high thermal conductivity layer is a layer of diamond.

29. The method for manufacturing the nitride semiconductor device according to claim 21,
wherein the high thermal conductivity layer is a layer of AlN.

30. A method for manufacturing a nitride semiconductor device, comprising:
forming a high thermal conductivity layer, on a surface of a first substrate, by vapor deposition, the high thermal conductivity layer having a thermal conductivity higher than a thermal conductivity of the first substrate;
surface bonding a second substrate onto a surface of the high thermal conductivity layer formed in said forming the high thermal conductivity layer; and
epitaxially growing GaN on a rear-surface of the first substrate as an intermediate layer, after said surface bonding.

31. The method for manufacturing the nitride semiconductor device according to claim 30, further including
thinning the first substrate between said surface bonding and said forming the first substrate nitride.

32. The method for manufacturing the nitride semiconductor device according to claim 31,
wherein the substrate has a surface on which p-n junction is formed, and the surface having contact with the thermal conductivity layer is mainly made of p-type silicon, and
the first substrate is thinned by selective etching removing n-type silicon in said thinning the first substrate.

33. The method for manufacturing the nitride semiconductor device according to claim 32,
wherein said thinning the first substrate includes, in advance, a process exposing an equivalent plane to a (100) plane on a surface of an n-type silicon substrate.

34. The method for manufacturing the nitride semiconductor device according to claim 31,
wherein, the first substrate is an SOI substrate having an outermost surface layer and a silicon oxide layer, and
in said thinning the first substrate, the SOI substrate is removed through the silicon oxide layer by selective etching, and the first substrate is thinned with only the outermost surface layer left.

35. The method for manufacturing the nitride semiconductor device according to claim 34,
wherein the first substrate is a carbonized SOI substrate.

36. The method for manufacturing the nitride semiconductor device according to claim 30,
wherein the high thermal conductivity layer is a layer of diamond.

37. The method for manufacturing the nitride semiconductor device according to claim 30,
wherein the high thermal conductivity layer is a layer of AlN.
